(19) United States
(12) Patent Application Publication
(10) Pub. No.: US 2026/0238195 A1
(43) Pub. Date: Aug. 13, 2026

(54) SIGNAL GENERATOR AND METHOD FOR OPERATING A SIGNAL GENERATOR

(71) Applicant: Robert Bosch GmbH, Stuttgart (DE)

(72) Inventors: Joachim Joos, Gerlingen (DE); Manuela Fischer, Reutlingen (DE); Patrick Naujoks, Esslingen (DE); Simon Geiselhart, Muensingen (DE)

(21) Appl. No.: 19/463,329

(22) Filed: Jan. 29, 2026

(30) Foreign Application Priority Data
Feb. 10, 2025 (DE) 10 2025 104 725.1

(51) Int. Cl. H03K 4/02

(52) U.S. Cl. CPC H03K 4/02

(57) ABSTRACT

A signal generator for generating at least one signal pulse in staircase form. The signal generator has a first transmission line with a first length, which is connected in series with a first voltage source for transmitting at least a first signal, wherein the first voltage source has a first level, and a second transmission line with a second length different from the first length, which is connected in parallel with the first transmission line, wherein the second transmission line is connected in series with a second voltage source for transmitting at least a second signal, and wherein the second voltage source has a second level.

### FIELD

The present disclosure relates to a signal generator that has at least two voltage sources and two transmission lines of different lengths.

### BACKGROUND INFORMATION

In the related art, a characterization is undertaken of semiconductor devices and corresponding circuits that are operated in a pulse mode. This can reduce self-heating effects and excessive energy losses that lead to the destruction of the component and/or the circuit. Pulse mode measurement is performed either via single-pulse measurement or multi-pulse measurement. By means of multi-pulse measurement, the accuracy of the characterization can be increased. For fast measurements, the edges of the signal pulse must be steep. However, both single-pulse and multi-pulse measurements can result in signal overshoot and undershoot, as well as unwanted oscillations. This phenomenon occurs particularly with broadband devices. The measurement points are only recorded once the unwanted oscillations have subsided. The duration of a measurement therefore increases.

### SUMMARY

The signal generator according to the present disclosure enables the generation of a signal pulse in staircase form. The signal generator also enables the generation of a signal pulse in other forms; in so doing, each form, including the staircase form, is optimized to accelerate a measurement process.

According to an example embodiment, the signal generator is designed with a first transmission line with a first length L₁ which is connected in series with a first voltage source for transmitting at least a first signal, wherein the first voltage source has a first level V₁. Furthermore, the signal generator according to the present disclosure is designed with a second transmission line with a second length L₂ different from the first length L₁, which is connected in parallel with the first transmission line, wherein the second transmission line is connected in series with a second voltage source for transmitting at least a second signal, and wherein the second voltage source has a second level V₂. With the aid of this setup, a signal pulse in staircase form can be generated. Other forms, such as a triangular form, can also be created by means of the above-mentioned setup. By forming the signal pulses, the number of required measurement points can be reduced. Thus, the time required for a measurement is reduced while maintaining the same measurement accuracy. In order to generate a signal pulse in staircase form, in particular, a second transmission line is chosen, the length L₂ of which is half as long as the length L₁ of the first transmission line. Furthermore, in order to generate a signal pulse in staircase form, the first level of the first voltage source is chosen to be half as large as the second level of the second voltage source.

Preferred developments are disclosed herein.

Preferably, a first switch for influencing the timing of the generation of the first signal is arranged after the first transmission line, and/or a second switch for influencing the timing of the generation of the second signal is arranged after the second transmission line. Initially, the first switch and the second switch are open. This charges the first transmission line and the second transmission line using a constant DC voltage. In order to generate a first signal propagating on the first transmission line, the first switch must be closed. As soon as the first switch is closed, the first signal from the first switch propagates with an amplitude with the value

$$- \frac{{V}_{1}}{2}$$

in the direction of the first voltage source. In order to generate a signal pulse in staircase form, when the relationships 2L₂=L₁ and V₂=2V₁ prevail, the second switch is closed precisely when the first signal from the first transmission line, which propagates from the first switch toward the first voltage source, has reached the midpoint of the first transmission line. Once the second switch is closed, the second signal propagates with an amplitude with the value

$$- \frac{{v}_{2}}{2}$$

from the second switch to the second voltage source. The second signal reaches the end of the second transmission line facing the second voltage source at the same time at which the first signal reaches the end of the first transmission line facing the first voltage source.

In one example embodiment, the first transmission line is terminated with a third switch and a first resistor to suppress unwanted signal reflections, and/or the second transmission line is terminated with a fourth switch and a second resistor to suppress unwanted signal reflections. The first resistor and the second resistor each have a value equal to the value of the characteristic resistance of the corresponding transmission line since all the energy is therefore absorbed by the two resistors. For example, if the first transmission line has a characteristic resistance with a value of 50 ohms, a first resistor with a value of 50 ohms is arranged. The same applies to the second transmission line and the second resistor. In particular, a slight time offset is set between the switching times of the third switch and the fourth switch so that the two transmission lines are not discharged at the same time. This reduces the steepness of the falling edge. The same result can also be achieved by adjusting the lengths L₁ and L₂.

Furthermore, preferably a third resistor for amplitude adjustment of the first signal is arranged after the first voltage source, and/or a fourth resistor for amplitude adjustment of the second signal is arranged after the second voltage source. Upon arrival at the third resistor and fourth resistor respectively, the first signal and second signal propagate back toward the respective transmission lines. The propagation of the signals depends on the voltage of the transmission lines. The transmission lines are charged with voltages V1 and V2 through the third resistor and/or the fourth resistor. The third and fourth resistors are preferably of the same size. For example, the third resistor and/or the fourth resistor have a value of approximately 500 kΩ.

To equalize the amplitudes of the first signal and the second signal, the third resistor has a value that is at least two orders of magnitude higher than the value of the impedance of the first transmission line, and/or the fourth resistor has a value that is at least two orders of magnitude higher than the value of the impedance of the second transmission line. By choosing such large values for the third resistor and/or the fourth resistor, the signal can be better decoupled.

It is further preferred that a first capacitor be arranged after the first transmission line to reduce the steepness of the rising edges of the signal, and/or that a second capacitor be arranged after the second transmission line to reduce the steepness of the rising edges of the signal. In so doing, the capacitors act as integrators.

In one example embodiment, the first transmission line and the second transmission line are part of a group of n transmission lines (1, 2, . . . , n) connected in parallel for generating an n-step signal pulse, where n is a natural number and is at least 2. All of the above descriptions of the design of the signal generator according to the present disclosure can be applied to the number of n−2 plus steps.

Advantageously, a control unit is arranged for switching on and off one and/or more transmission lines. By means of the same control unit, among other things, the switching times of the switches and the levels of the voltage sources can also be set.

The present disclosure also relates to a method in which a first switch and/or a second switch is closed to generate the first signal and/or the second signal. To influence the timing of the generation of the first signal or the second signal, either the first switch or the second switch is closed with a time offset from the other switch.

In a further method step, the third switch and/or the fourth switch are closed to suppress unwanted signal reflections. Furthermore, closing of the third switch or of the fourth switch with a time offset from the other switch can result in the reduction of the steepness of the falling edge of the signal pulse.

Preferably, in a further method step, a number m of transmission lines connected in parallel can be switched off via the control unit to reduce energy consumption, wherein the number m is a positive natural number that is at least two less than the number n.

### BRIEF DESCRIPTION OF THE DRAWINGS

In the following, exemplary embodiments of the present disclosure are described in detail with reference to the figures.

FIG. 1 shows a block diagram of the signal generator according to the an example embodiment.

FIG. 2 shows a voltage diagram of the signal generator according to the present disclosure, plotted against time.

FIG. 3 shows a voltage diagram of an n-step signal generator, plotted against time.

### DETAILED DESCRIPTION OF EXAMPLE EMBODIMENTS

Preferably, identical components, elements, and/or units are provided with identical reference signs in all figures.

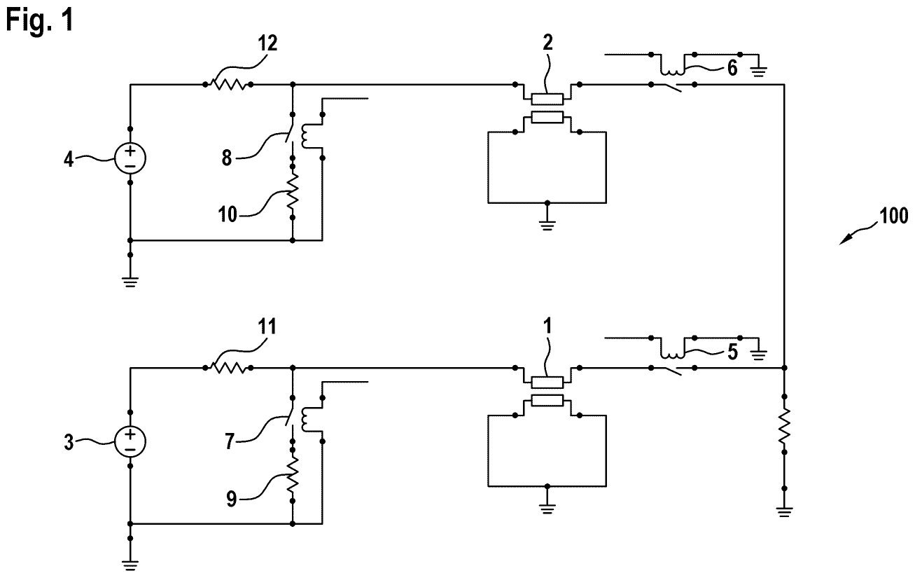

FIG. 1 shows a signal generator 100 for generating at least one signal pulse in staircase form. The signal generator 100 has a first transmission line 1 and a second transmission line 2. The first transmission line has a first length L₁ and is connected in series with a first voltage source 3 for transmitting at least a first signal, wherein the first voltage source 3 has a first level V₁. The second transmission line 2 has a second length L₂ different from the first length L₁ and is connected in parallel with the first transmission line 1. The second transmission line 2 is connected in series with a second voltage source 4 for transmitting at least a second signal, wherein the second voltage source 4 has a second level V₂.

The signal generator shown in FIG. 1 generates a signal pulse in a two-step staircase form. In the present embodiment, a first switch 5 for influencing the timing of the generation of the first signal is arranged after the first transmission line 1, and/or a second switch 6 for influencing the timing of the generation of the second signal is arranged after the second transmission line 2. Furthermore, in the present case, the first transmission line 1 is terminated with a third switch 7 and a first resistor 9 to suppress unwanted signal reflections, and the second transmission line 2 is terminated with a fourth switch 8 and a second resistor 10 to suppress unwanted signal reflections.

After the first voltage source 3, a third resistor 11 is arranged for amplitude adjustment of the first signal, and after the second voltage source 4, a fourth resistor 12 is arranged for amplitude adjustment of the second signal. The third resistor 11 has a value that is at least two orders of magnitude higher than the value of the impedance of the first transmission line 1, to equalize the amplitudes of the first signal and the second signal, and the fourth resistor 12 has a value that is at least two orders of magnitude higher than the value of the impedance of the second transmission line 2, also to equalize the amplitudes of the first signal and the second signal.

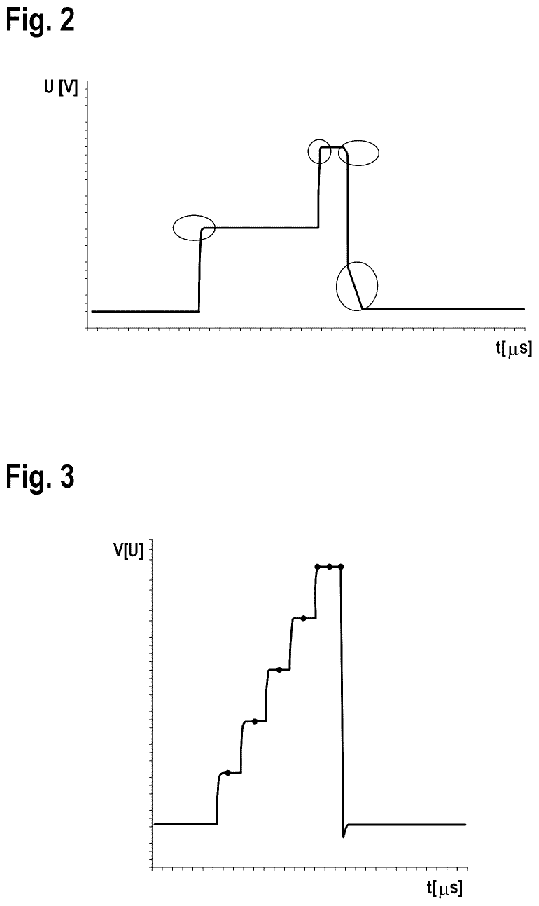

FIG. 2 shows a two-step signal pulse in staircase form. In this case, a first capacitor is arranged after the first transmission line to reduce the steepness of the rising edges of the signal and/or a second capacitor is arranged after the second transmission line to reduce the steepness of the rising edges of the signal. The reduction of the steepness of the falling edges can be achieved by setting a time offset between the switching times of the third switch and the fourth switch.

FIG. 3 shows an n-step signal pulse in staircase form where n=5. In the present embodiment, the first transmission line 1 and the second transmission line 2 are part of a group of n=5 transmission lines (1, 2, . . . , n=5) connected in parallel for generating an n-step signal pulse, where n is in each case a natural number and is at least 2. The signal generator has a control unit for switching on and off one and/or more transmission lines.

1-11. (canceled)

12. A signal generator for generating at least one signal pulse in staircase form, comprising:
a first transmission line having a first length, the first transmission line being connected in series with a first voltage source for transmitting at least a first signal, wherein the first voltage source has a first level; and
a second transmission line having a second length different from the first length, wherein the second transmission line is connected in parallel with the first transmission line, wherein the second transmission line is connected in series with a second voltage source for transmitting at least a second signal, and wherein the second voltage source has a second level.

13. The signal generator according to claim 12, wherein at least one of: (i) a first switch for influencing a timing of generation of the first signal is arranged after the first transmission line, or (ii) a second switch for influencing a timing of generation of the second signal is arranged after the second transmission line.

14. The signal generator according to claim 12, wherein at least one of: (i) the first transmission line is terminated with a third switch and a first resistor to suppress unwanted signal reflections, or (ii) the second transmission line is terminated with a fourth switch and a second resistor to suppress unwanted signal reflections.

15. The signal generator according to claim 12, wherein at least one of: (i) a third resistor for amplitude adjustment of the first signal is arranged after the first voltage source, or (ii) a fourth resistor for amplitude adjustment of the second signal is arranged after the second voltage source.

16. The signal generator according to claim 15, wherein at least one of: (i) the third resistor has a value that is at least two orders of magnitude higher than a value of an impedance of the first transmission line to equalize amplitudes of the first signal and the second signal, or (ii) the fourth resistor has a value that is at least two orders of magnitude higher than a value of an impedance of the second transmission line to equalize the amplitudes of the first signal and the second signal.

17. The signal generator according to claim 12, wherein at least one of: (i) a first capacitor is arranged after the first transmission line to reduce a steepness of rising edges of the signal, or (ii) a second capacitor is arranged after the second transmission line to reduce steepness of rising edges of the signal.

18. The signal generator according to claim 12, wherein the first transmission line and the second transmission line are part of a group of n transmission lines connected in parallel for generating an n-step signal pulse, wherein n is a natural number and is at least 2.

19. The signal generator according to claim 12, wherein a control unit is arranged for switching on and off one or more of the first and second transmission lines.

20. A method for operating a signal generator, the signal generator for generating at least one signal pulse in staircase form, including:
a first transmission line having a first length, the first transmission line being connected in series with a first voltage source for transmitting at least a first signal, wherein the first voltage source has a first level, and
a second transmission line having a second length different from the first length, wherein the second transmission line is connected in parallel with the first transmission line, wherein the second transmission line is connected in series with a second voltage source for transmitting at least a second signal, and wherein the second voltage source has a second level,
wherein at least one of: (i) a first switch for influencing a timing of generation of the first signal is arranged after the first transmission line, or (ii) a second switch for influencing a timing of generation of the second signal is arranged after the second transmission line,
the method comprising the following steps of:
closing the first switch and/or the second switch to generate the first signal and/or the second signal; and
closing the first switch or the second switch with a time offset to influence a timing of the generation of the first signal and/or the second signal.

21. A method for operating a signal generator, the signal generator for generating at least one signal pulse in staircase form, including:
a first transmission line having a first length, the first transmission line being connected in series with a first voltage source for transmitting at least a first signal, wherein the first voltage source has a first level, and
a second transmission line having a second length different from the first length, wherein the second transmission line is connected in parallel with the first transmission line, wherein the second transmission line is connected in series with a second voltage source for transmitting at least a second signal, and wherein the second voltage source has a second level,
wherein at least one of: (i) the first transmission line is terminated with a third switch and a first resistor to suppress unwanted signal reflections, or (ii) the second transmission line is terminated with a fourth switch and a second resistor to suppress unwanted signal reflections,
the method comprising the following:
closing the third switch and/or the fourth switch to suppress unwanted signal reflections, and
closing the third switch or the fourth switch with a time offset to reduce steepness of a falling edge of the signal pulse.

22. The method according to claim 20, wherein the first transmission line and the second transmission line are part of a group of n transmission lines connected in parallel for generating an n-step signal pulse, wherein n is a natural number and is at least 2, and wherein a number m of transmission lines connected in parallel are switched off via a control unit to reduce energy consumption, wherein the number m is a positive natural number that is at least two less than the number n.
